(19) United States
(12) Patent Application Publication
(10) Pub. No.: US 2010/0034231 A1
(43) Pub. Date: Feb. 11, 2010

(54) SEMICONDUCTOR LASER

(75) Inventors: Kazuhisa FUKUDA, Kawasaki (JP); Chiaki SASAOKA, Kawasaki (JP); Kentaro TADA, Kawasaki (JP); Toshiaki IGARASHI, Kawasaki (JP); Fumito MIYASAKA, Kawasaki (JP); Keiro KOMATSU, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/535,163

(22) Filed: Aug. 4, 2009

(30) Foreign Application Priority Data
Aug. 6, 2008 (JP) 2008-203133

(51) Int. Cl. H01S 5/028; H01S 5/00

(52) U.S. Cl. 372/49.01; 372/43.01

(57) ABSTRACT

A semiconductor laser, which emits a laser beam from an edge surface of an active layer (5), is provided with a protective film (20), arranged on the edge surface from which the laser beam is emitted, and formed of a single-layer or a multilayer dielectric film. Hydrogen concentration distribution in the protective film (20) is approximately flat. The active layer (5) is formed of a group-III nitride semiconductor including Ga as a constituent element. The protective film (20) is formed of at least a first protective film (21) that is in direct contact with an edge surface of the active layer (5), and a second protective film (22) that is in contact with the first protective film (21). A ratio of hydrogen concentration of the first protective film (21) with respect to hydrogen concentration of the second protective film (22) is not less than 0.5 and not more than 2.

### REFERENCE TO RELATED APPLICATION

This application is based upon and claims the benefit of the priority of Japanese patent application No. 2008-203133, filed on Aug. 6, 2008, the disclosure of which is incorporated herein in its entirety by reference thereto.

### TECHNICAL FIELD

The present invention relates to a semiconductor laser, and in particular to a semiconductor laser using a group-III nitride semiconductor in an active layer.

### BACKGROUND

Since blue violet light emissions can be obtained with high efficiency, group-III nitride semiconductors represented by gallium nitride have been attracting attention as a material for a semiconductor laser such as a light emitting diode (LED), a laser diode (LD), or the like. Among these, there is anticipation with regard to the LD as a light source for large volume optical disk devices, and development of high output LDs as a writing light source is being vigorously promoted in recent years.

FIG. 13 shows a structure of a typical gallium nitride optical semiconductor device according to a conventional example. This optical semiconductor device is manufactured by stacking an n-type cladding layer 102, an optical guide layer 103, an active layer 104, an optical guide layer 105, and a p-type cladding layer 106, in order, on a GaN substrate 101, after which the p-type cladding layer 106 is formed in a ridge shape by dry etching. The p-type cladding layer 106 is covered by an insulating film 107, except for a top part of a ridge portion 106a, and a p-type electrode 108 is arranged at least on the ridge portion 106a. An n-type electrode 109 is arranged on a rear surface of the GaN substrate 101. Current confinement is realized by the p-type electrode 108, and by adjusting ridge width and ridge height of the ridge portion 106a, control of lateral mode is realized. A laser beam is emitted from a resonator mirror (not shown in the drawings) formed by cleavage, at edge surfaces of both sides in a longitudinal axis direction of the ridge portion 106a (vertical direction of plane of paper with regard to FIG. 13). An edge surface protective film (not shown in the drawings) formed of a dielectric is formed on a surface of the resonator mirror.

Requirements of the edge surface protective film that are cited are: that a laser beam is not absorbed, that a desired reflectance is obtained, that adherence to the semiconductor is good, and the like, and from a viewpoint of manufacturing, it is important that film formation with good controllability and productivity be possible. From this type of viewpoint, for the edge surface protective film, in general an oxide such as Al₂O₃, SiO₂, TiO₂, ZrO₂, Ta₂O₅, Nb₂O₅ or the like, a fluoride such as MgF₂, CaF₂ or the like, or a nitride such as AlN, Si₃N₄ or the like are used in film formation by a method such as sputtering, CVD, deposition, and the like.

In a semiconductor laser having, as the edge surface protective film, an anti-reflecting (AR) film formed on a laser beam emission side edge surface, and a high-reflecting (HR) film formed on an edge surface of an opposite side, laser beam emission efficiency is improved, and critical light output reaching the Catastrophic Optical Damage (COD), (the critical light output being referred to below as “COD level”) is improved. As a result, high output operation in a relatively short time is possible, but the edge surface protective film may be damaged by high output operation for a long time, and reliability of the semiconductor laser deteriorates. Consequently, in the semiconductor laser, in order to inhibit damage to the edge surface protective film and improve life span, there is a proposal in, for example, Patent Document 1, to reduce internal stress of a coating film (edge surface protective film).

Furthermore, with regard to a nitride semiconductor laser, an interfacial reaction of the edge surface protective film and the semiconductor occurs due to high output driving for a long time, and the interfacial reaction decreases the reliability. Consequently, in order to inhibit the interfacial reaction of the edge surface protective film and the semiconductor, there is a proposal in, for example, Patent Document 2, to have a film density of an AR coating film (edge surface protective film), which is in contact with a semiconductor layer, greater than or equal to ¾ of an ideal density of material forming the AR coating film.

Furthermore, in Patent Document 3, before forming an edge surface coating film (edge surface protective film), a resonator edge surface is exposed to an inert gas plasma atmosphere, and the resonator edge surface is cleaned and flattened by heating to a temperature of at least 30° C. and not exceeding 700° C. in a vacuum or an inert gas atmosphere. Furthermore, in Patent Document 3, by thinly forming a bonding layer formed of a metal such as Al, an oxynitride of the metal, or the like, between the edge surface coating film (edge surface protective film) and the resonator edge surface, adherence of the edge surface coating film to the resonator edge surface is increased and reliability is improved.

Furthermore, in Patent Document 4, by providing a first dielectric film to which hydrogen is added, on at least one resonator edge surface, by providing a second dielectric, having a thickness of an extent that prevents diffusion of the hydrogen and does not affect edge surface reflectance, between the first dielectric film and the resonator edge surface, and providing a third dielectric film, through which hydrogen passes, between the resonator edge surface and the second dielectric film, in a case where there is a hydrogenated film in an edge surface coating film (edge surface protective film), even if the semiconductor laser is exposed to a high temperature state, it is possible to prevent edge surface coating film delamination and degeneration of the edge surface coating film.

### [Patent Document 1]

JP Patent Kokai Publication No. JP-P2002-223026A

### [Patent Document 2]

JP Patent Kokai Publication No. JP-P2007-165711A

### [Patent Document 3]

JP Patent Kokai Publication No. JP-P2002-335053A

### [Patent Document 4]

JP Patent Kokai Publication No. JP-P2005-333157A

### SUMMARY

The disclosures of the above mentioned Patent Documents are incorporated herein in their entirely with reference thereto. Now, the following analyses are given by the present invention.

According to an experiment of the inventors, when a nitride semiconductor laser, having a life span of 1000 hours or more when operated at an output of 100 mW, has output increased to operate at 150 mW, change in operating current during energized operation at an elevated output level was observed, and ultimately a problem occurred in that oscillation suddenly stopped.

When a cause of this was investigated, it was understood that this problem occurred due to edge surface destruction of an edge surface on a laser beam emission side, among resonator edge surfaces, and that this edge surface destruction occurred in the following way. In a semiconductor laser edge surface at high output driving, due to absorption of a laser beam caused by point defects introduced at surface level or when forming a protective film, interfacial degeneration layer, or the like, the temperature of a laser beam emission portion increases. Since an edge surface protective film formed on the laser beam emission edge surface expands due to this temperature increase, compressive stress on the edge surface protective film, due to difference of thermal expansion coefficient from the semiconductor, increases, and local film delamination may occur. In this case, since the edge surface reflectance changes, change of operating current is caused. Furthermore, a semiconductor edge surface is in an atmosphere-exposed state, and a crystal region close to the edge surface deteriorate. The crystal region that has deteriorated in this way, in order to absorb the laser beam, has an even higher temperature close to the edge surface. A vicious circle occurs where edge surface deteriorates further, due to this heat, and ultimately results in COD.

However, in the semiconductor lasers proposed in Patent Documents 1, 2, and 3, it is not possible to completely inhibit this type of local delamination of the edge surface protective film.

Furthermore, in the semiconductor laser proposed in Patent Document 4, with regard to the edge surface protective film, when hydrogen concentration distribution in the third dielectric film is not uniform, it is not possible to inhibit the film expansion. Furthermore, with regard to the second dielectric film that prevents diffusion of the hydrogen, since high precision is necessary, stress becomes quite large. As a result, it is not possible to completely inhibit the local film delamination of the edge surface coating film.

It is a principal object of the present invention to provide a nitride semiconductor laser device having high COD resistance, high output and a long life span, and in which it is possible to inhibit film delamination of an edge surface protective film on a resonator edge surface when driving with high output for a long time.

In one aspect of the present invention, a semiconductor laser for emitting a laser beam from an edge surface of an active layer is provided with a protective film arranged on the edge surface from which the laser beam is emitted, and is formed of a single-layer or multilayer dielectric film, wherein hydrogen concentration distribution in the protective film is approximately flat.

The meritorious effects of the present invention are summarized as follows.

According to the present invention, since the hydrogen concentration distribution in the protective film formed on a laser beam emission side is made flat, when a laser is operated at a high output for a long time, it is possible to inhibit diffusion of hydrogen in the protective film caused by local heat generation in a laser beam emission part, and in this way, it is possible to inhibit stress changes in the protective film.

### BRIEF DESCRIPTION OF THE DRAWINGS

FIG. 1A is a cross-section drawing schematically showing a configuration of a semiconductor laser according to a first exemplary embodiment of the present invention and FIG. 1B is a partial cross-section drawing along line X-X′.

FIGS. 2A-2C are first process cross-section drawings schematically showing a method of manufacturing the semiconductor laser according to the first exemplary embodiment of the present invention.

FIGS. 3A-3C are second process cross-section drawings schematically showing a method of manufacturing the semiconductor laser according to the first exemplary embodiment of the present invention.

FIGS. 4A-4C are third process cross-section drawings schematically showing a method of manufacturing the semiconductor laser according to the first exemplary embodiment of the present invention.

FIG. 5 is a drawing showing a relationship between AR reflectance and thicknesses d₁ and d₂ of a first protective film and a second protective film of the semiconductor laser according to the first exemplary embodiment of the present invention.

FIG. 6 is a drawing showing one example of a SIMS analysis result of hydrogen concentration distribution in an AR film of the semiconductor laser according to the first exemplary embodiment of the present invention.

FIG. 7 is a drawing showing a relationship of a film formation condition and film stress of a dielectric film used in the AR film of the semiconductor laser according to the first exemplary embodiment of the present invention.

FIG. 8 is a drawing showing a relationship of device life span and hydrogen concentration ratio in the AR film of the semiconductor laser according to the first exemplary embodiment of the present invention.

FIG. 9 is a drawing showing a relationship of device life span and the second protective film (Al₂O₃ film) thickness of the semiconductor laser according to the first exemplary embodiment of the present invention.

FIG. 10 is a drawing showing a relationship of device life span and the first protective film (TiO₂ film) thickness of the semiconductor laser according to the first exemplary embodiment of the present invention.

FIG. 11 is a drawing showing a relationship of device life span and internal stress of the second protective film (Al₂O₃ film) of the semiconductor laser according to the first exemplary embodiment of the present invention.

FIG. 12 is a drawing showing a relationship of device life span and total stress of the AR film of the semiconductor laser according to the first exemplary embodiment of the present invention.

FIG. 13 is a cross-section drawing schematically showing a structure of a conventional semiconductor laser having a ridge type waveguide structure.

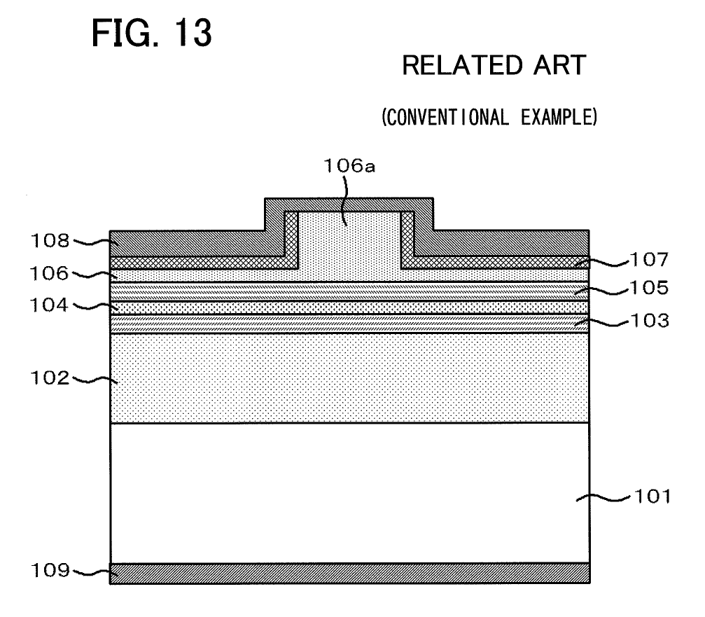

### PREFERRED MODES

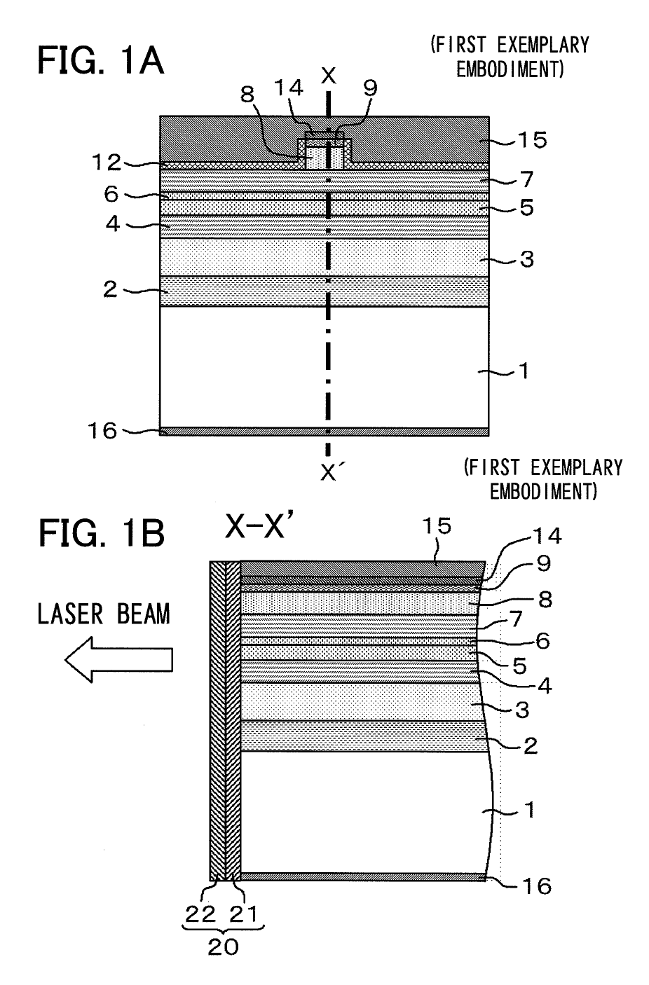

In a embodiment of the present invention, a semiconductor laser for emitting a laser beam from an edge surface of an active layer (5 in FIGS. 1A and 1B) is provided with a protective film (20 in FIG. 1B) arranged on the edge surface from which the laser beam is emitted, and is formed of a single-layer or a multilayer dielectric film, wherein hydrogen concentration distribution in the protective film (20 in FIG. 1B) is approximately flat.

### Exemplary Embodiment 1

A semiconductor laser according to a first exemplary embodiment of the present invention is described using the drawings. FIG. 1A is a cross-section drawing schematically showing a configuration of the semiconductor laser according to the first exemplary embodiment of the present invention, and FIG. 1B is a partial cross-section drawing along line X-X′. Moreover, FIG. 1A is a drawing viewed from a cross-section perpendicular to a resonator edge surface and FIG. 1B is a cross-section parallel to the resonator edge surface and is a drawing of a vicinity of a laser emission edge surface.

Referring to FIG. 1A, the semiconductor laser is a ridge stripe type of device in which a laser beam is emitted from an edge surface of a 3-period multiple quantum well active layer 5. In the semiconductor laser, a Si-doped n-type GaN layer 2, an n-type cladding layer 3, an n-type optical confinement layer 4, the 3-period multiple quantum well active layer 5, a cap layer 6, and a p-type optical confinement layer 7 are stacked, in order, on an n-type GaN substrate 1; a p-type cladding layer 8, a p-type contact layer 9, and a p-type electrode 14 are stacked in a striped form, in order, on the p-type optical confinement layer 7; a SiO₂ film 12 is formed on a side wall surface of the p-type cladding layer 8, a side wall surface of the p-type contact layer 9, and on the p-type optical confinement layer 7; a cover electrode 15 is coated on the p-type electrode 14 and the SiO₂ film 12; and an n-type electrode 16 is formed on a rear surface (bottom surface of FIG. 1A) of the n-type GaN substrate 1.

Referring to FIG. 1B, in the semiconductor laser, two end surfaces in a longitudinal axis direction of the p-type cladding layer 8 form resonator edge surfaces that are formed by cleavage, and the edge surface protective film that is a dielectric on surfaces of the resonator edge surfaces is formed. An anti-reflecting (AR) film 20 is formed as a protective film on a laser beam emission side edge surface, among the resonator edge surfaces, and a high-reflecting (HR) film (not shown in the drawings) is formed as a protective film on an edge surface of an opposing side.

An n-type GaN (0001) substrate, for example, can be used for the n-type GaN substrate 1.

For the Si-doped n-type GaN layer 2, for instance, a Si-doped n-type GaN layer with Si concentration of 4×10¹⁷ cm⁻³, e.g., can be used, and thickness can be 1 μm, e.g.

For the n-type cladding layer 3, for instance, Si-doped n-type Al0.1Ga0.9N with Si concentration of 4×10¹⁷ cm⁻³, e.g., can be used, and thickness can be 2 μm, e.g.

For the n-type optical confinement layer 4, for instance, Si-doped n-type GaN of Si concentration of 4×10¹⁷ cm⁻³, e.g., can be used, and thickness can be 0.1 μm, e.g.

The 3-period multiple quantum well active layer 5 is a layer formed of a group-III nitride semiconductor including Ga as a constituent element. For the 3-period multiple quantum well active layer 5, it is possible to use a stack, in order, from a bottom layer, of, for instance, a well layer of 3 nm thickness formed of In0.15Ga0.85N, and a barrier layer of 4nm thickness formed of Si-doped In0.01Ga0.99N of Si concentration of 1×10¹⁸ cm⁻³.

For the cap layer 6, it is possible to use, for instance, Mg-doped p-type Al0.2Ga0.8N of Mg concentration of 2×10¹⁹ cm⁻³, and thickness can be 10 nm.

For the p-type optical confinement layer 7, for instance, Mg-doped p-type GaN of Mg concentration of 2×10¹⁹ cm⁻³ can be used, and thickness can be 0.1 μm.

For the p-type cladding layer 8, it is possible to use, for instance, Mg-doped p-type Al0.1Ga0.9N of Mg concentration of 1×10¹⁹ cm⁻³, and thickness can be 0.5 μm. The p-type cladding layer 8 is formed in a stripe form in FIGS. 1A and 1B, but may be formed in a ridge form using dry etching.

For the p-type contact layer 9, for instance, Mg-doped p-type GaN of Mg concentration of 1×10²⁰ cm⁻³ can be used, and thickness can be 0.02 μm. The p-type contact layer 9 is formed in a stripe form corresponding to the p-type Al0.1Ga0.9N cladding layer 8.

The SiO₂ film 12 is an insulating film formed of SiO₂ and covers the side wall surface of the p-type cladding layer 8, the side wall face of the p-type contact layer 9, and the top of the p-type optical confinement layer 7.

For the p-type electrode 14, for instance, Pd/Pt deposited by an electron beam can be used.

For the cover electrode 15, for instance, a metal layered body can be used in which 50 nm of Ti, 100 nm of Pt, and 2 μm of Au, deposited by sputtering, are stacked, in order.

For the n-type electrode 16, for instance, a metal layered body can be used, being obtained by vacuum deposition of 5 nm of Ti, 20 nm of Al, 10 nm of Ti, and 500 nm of Au, in order, from the n-type GaN substrate 1 side.

The AR film 20 is formed of a single-layer or a multi-layer dielectric film. For the AR film 20, it is preferable to provide a dielectric material including any of Ti, Zr, Nb, Ca, and Mg, in a region in a vicinity of an interface of edge surfaces of the semiconductor (1 to 7), and in particular, a dielectric film including Ti is desirable. Since these elements have a property of combining easily with hydrogen, it is possible to preferably inhibit hydrogen diffusion in the film. In particular, by having a layer including Ti, it is possible to both optimally control the reflectance, and to reduce total stress S=σ·d (N/m), obtained by multiplying internal stress σ of the protective film by film thickness d; local film delamination of the protective film from the semiconductor is inhibited; and device reliability is improved. The AR film 20 can be stably formed by appropriately combining refractive index and film thickness, from an oxide such as Al₂O₃, SiO₂, TiO₂, ZrO₂, Ta₂O₅, Nb₂O₅ or the like, a fluoride such as MgF₂, CaF₂ or the like, and a nitride such as AlN, Si₃N₄ or the like, formed by sputtering or deposition.

For the AR film 20, in a case of a single-layer film, with regard to film thickness d thereof, a laser oscillation wavelength λ is preferably λ/2n or less for a refractive index n of a dielectric film, and more preferably is λ/4n or less.

For the AR film 20, in a case of a multilayer film, among dielectric materials, for a first protective film 21, with regard to the laser oscillation wavelength λ, a material having a high refractive index, for example, TiO₂ (refractive index 2.6), Nb₂O₅ (refractive index 2.5), ZrO₂ (refractive index 2.2) or the like, is preferably used; and for a second protective film 22, among the dielectric materials, a material having a low refractive index, for example, Al₂O₃ (refractive index 1.7) or SiO₂ (refractive index 1.4) is preferably selected. In a case of forming 2 layers of the AR film 20 with these materials, by having a thickness d₁ of the first protective film 21 (refractive index n₁) and a thickness d₂ of the second protective film 22 (refractive index n₂) in ranges of 0<d₁≦λ/4n₁, and 0<d₂≦λ/2n₂, preferable reflectance control is possible, and ranges of 0<d₁≦10 nm, and 0<d₂≦λ/4n₂ are more preferable.

With regard to the AR film 20, in order to decrease total stress in a direction of compression, it is preferable to reduce as much as possible internal stress in a direction of compression in the dielectric film constituting the AR film 20. The internal stress of the dielectric film can be controlled by a method of producing the film or a condition of producing the film. The total stress S=σ×d (σ₁×d₁+σ₂×d₂), obtained by multiplying the film stress σ (σ₁, σ₂), when estimated with the single-layer film, by the thicknesses d (d₁, d₂) utilized in the AR film, is preferably larger than 0 N/m and less than or equal to 10 N/m, and more preferably is less than or equal to 2 N/m.

It is desirable that the AR film 20 has an edge surface reflectance with respect to the laser beam of 0.1 to 30%. Total film thickness of the AR film 20 is preferably made as thin as possible, in a range in which a preferable reflectance is obtained. In this way, since it is possible to reduce the total stress in a direction of compression of the AR film 20, it is possible to inhibit local film delamination of the AR film 20 when driving a high output laser.

In the AR film 20, the hydrogen concentration distribution in a direction of thickness is preferably approximately flat. In this way, since it is possible to inhibit local changes of stress distribution in the AR film 20 from when a high output laser is driven, film delamination is inhibited. The hydrogen concentration distribution in the AR film 20 can be flattened by a method of forming a film using vacuum film forming technology, such as sputtering, deposition, or the like, while adding hydrogen to an atmosphere during film formation and adjusting flow; or a method of adequately normalizing a semiconductor surface by heat treatment or plasma cleaning before film formation, to reduce hydrogen concentration in the film. With regard to the hydrogen concentration in a vicinity of a surface in the AR film 20, a ratio of the hydrogen concentration in the vicinity of an interface with the semiconductor (1 to 7) is preferably greater than or equal to 0.5 and less than or equal to 2.

A HR film (not shown in the drawings) is a multilayer film in which a low refractive index dielectric film and a high refractive index dielectric film are combined, and it is desirable that reflectance with respect to the laser beam be 70 to 99%. The HR film can be stably formed by appropriately combining refractive index and film thickness, from an oxide such as Al₂O₃, SiO₂, TiO₂, ZrO₂, Ta₂O₅, Nb₂O₅ or the like, a fluoride such as MgF₂, CaF₂ or the like, or a nitride such as AlN, Si₃N₄ or the like, formed by sputtering or deposition, and it is possible to increase extraction efficiency of the laser beam and to have high output operation of the laser.

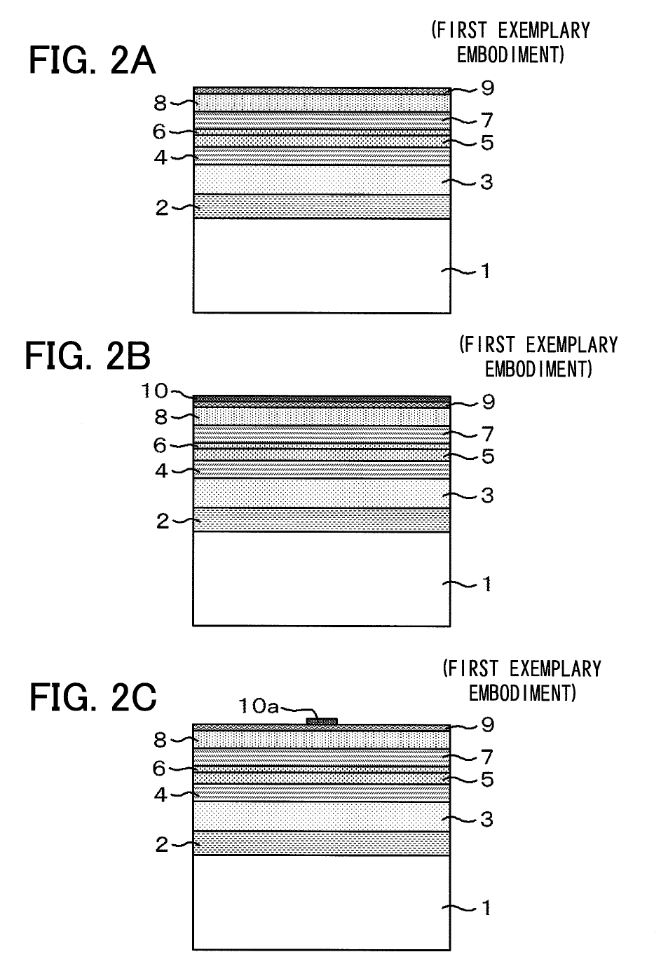

Next, a method of manufacturing the semiconductor laser according to the first exemplary embodiment of the present invention is described using the drawings. FIG. 2A to FIG. 4C are process cross-section drawings schematically showing the method of manufacturing the semiconductor laser according to the first exemplary embodiment of the present invention.

As a prerequisite condition in the manufacturing of the semiconductor laser it is possible to use a 300 hPa low pressure MOVPE (metalorganic vapor phase epitaxy) apparatus. A mixed gas of hydrogen and nitrogen can be used as a carrier gas, and trimethylgallium (TMG), trimethylaluminum (TMA), and trimethylindium (TMI), can be used, respectively, as Ga, Al, and In sources; silane (SiH₄) can be used for n-type dopant, and Bis(cyclopentadienyl)magnesium (Cp₂ Mg) can be used for p-type dopant.

First, after inputting the n-type GaN substrate 1 formed of the n-type GaN (0001) substrate into the low pressure MOVPE apparatus, the temperature of the n-type GaN substrate 1 is raised while feeding NH₃, and growth is started at a point in time at which growth temperature is reached. The Si-doped n-type GaN layer 2 of Si concentration of 4×10¹⁷ cm⁻³ is grown on the n-type GaN substrate 1 until a thickness of 1 μm is reached; the n-type cladding layer 3 formed of Si-doped n-type Al0.1Ga0.9N of Si concentration of 4×10¹⁷ cm⁻³ is grown on the Si-doped n-type GaN 2 until a thickness of 2 μm is reached; and the n-type optical confinement layer 4 formed of the Si-doped n-type GaN layer of Si concentration of 4×10¹⁷ cm⁻³ is grown on the n-type cladding layer 3 until a thickness of 0.1 μm is reached. Continuing, by growing a well layer formed of In0.15Ga0.85N on the n-type optical confinement layer 4 until a thickness of 3 nm is reached, and growing a barrier layer formed of Si-doped In0.01Ga0.99N of Si concentration of 1×10¹⁸ cm⁻³ on the well layer until a thickness of 4 nm is reached, the 3-period multiple quantum well active layer 5 is formed. Continuing, a cap layer 6 formed of Mg-doped p-type Al0.2Ga0.8N of Mg concentration 2×10¹⁹ cm⁻³ is grown on the 3-period multiple quantum well active layer 5 until a thickness of 10 nm is reached, and the p-type optical confinement layer 7 formed of the Mg-doped p-type GaN of MG concentration of 2×10¹⁹ cm⁻³ is grown on the cap layer 6 until a thickness of 0.1 μm is reached. Continuing, the p-type cladding layer 8 formed of Mg-doped p-type Al0.1Ga0.9N of Mg concentration of 1×10¹⁹ cm⁻³ is grown on the p-type optical confinement layer 7 until a thickness of 0.5 μm is reached, and the p-type contact layer 9 formed of Mg-doped p-type GaN of Mg concentration of 1×10²⁰ cm⁻³ is grown on the p-type cladding layer 8 until a thickness of 20 nm is reached (step A1; refer to FIG. 2A).

Growth of the GaN layer (the Si-doped n-type GaN layer 2, the n-type optical confinement layer 4, the p-type optical confinement layer 7, and the p-type contact layer 9) can be performed at a substrate temperature of 1080° C., a TMG feed rate of 58 μmol/min, and an NH₃ feed rate of 0.36 mol/min. Furthermore, growth of an AlGaN layer (the n-type cladding layer 3, the cap layer 6, and the p-type cladding layer 8) can be performed at a substrate temperature of 1080° C., a TMA feed rate of 36 μmol/min, a TMG feed rate of 58 μmol/min, and a NH₃ feed rate of 0.36 mol/min. Furthermore, growth of an InGaN layer (the 3-period multiple quantum well active layer 5), at a substrate temperature of 800° C., a TMG feed rate of 8μ mol/min, and an NH₃ feed rate of 0.36 mol/min, can be performed with a TMI feed rate of 48 μmol/min in the well layer, and of 3 μmol/min in the barrier layer.

Next, a SiO₂ film 10 is formed on the p-type contact layer 9 of a wafer fabricated according to step A1 (step A2; refer to FIG. 2B).

Next, a SiO₂ stripe 10a of width 1.3 μm is formed by a photolithography method (step A3; refer to FIG. 2C).

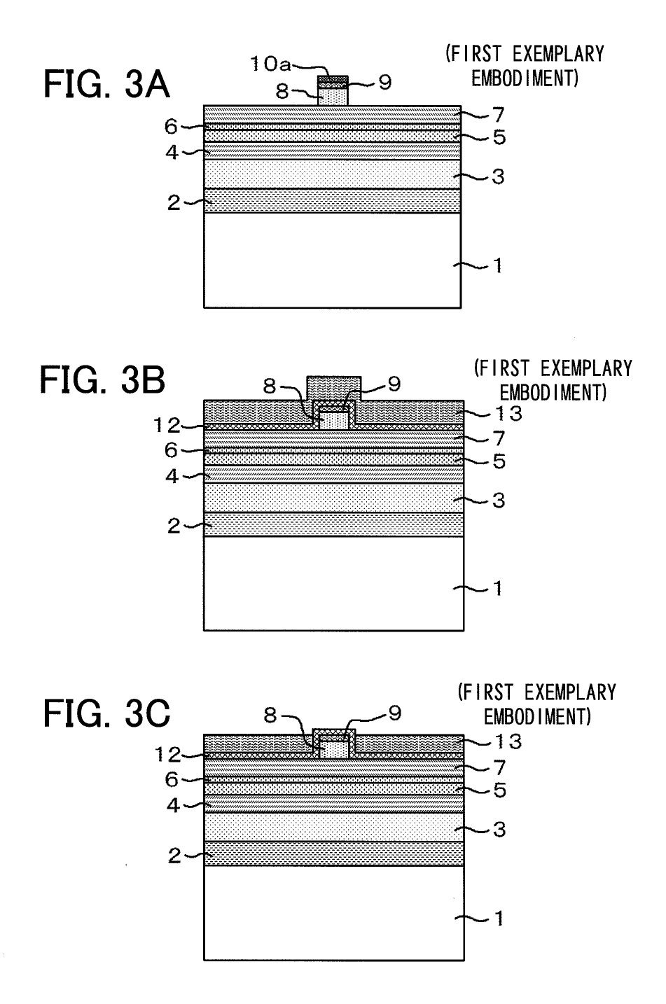

Next, by dry etching the SiO₂ stripe 10a as a mask, the p-type contact layer 9 and the p-type cladding layer 8 are removed until the p-type optical confinement layer 7 appears (step A4; refer to FIG. 3A). In this way, the p-type cladding layer 8 and the p-type contact layer 9 of a stripe form are formed on the p-type optical confinement layer 7. Moreover, a part of the p-type cladding layer 8 may be removed to form the p-type cladding layer 8 in a ridge structure.

Next, the SiO₂ stripe 10a is removed, the SiO₂ film 12 is deposited on the p-type optical confinement layer 7 that includes the p-type contact layer 9 and the p-type cladding layer 8, and thereafter, a resist 13 is thickly coated on the SiO₂ film 12 (step A5; refer to FIG. 3B).

Next, by removing a part of the resist 13 by etch-back in an oxygen plasma, a ridge top portion of the SiO₂ film 12 is made to jut out (step A6; refer to FIG. 3C).

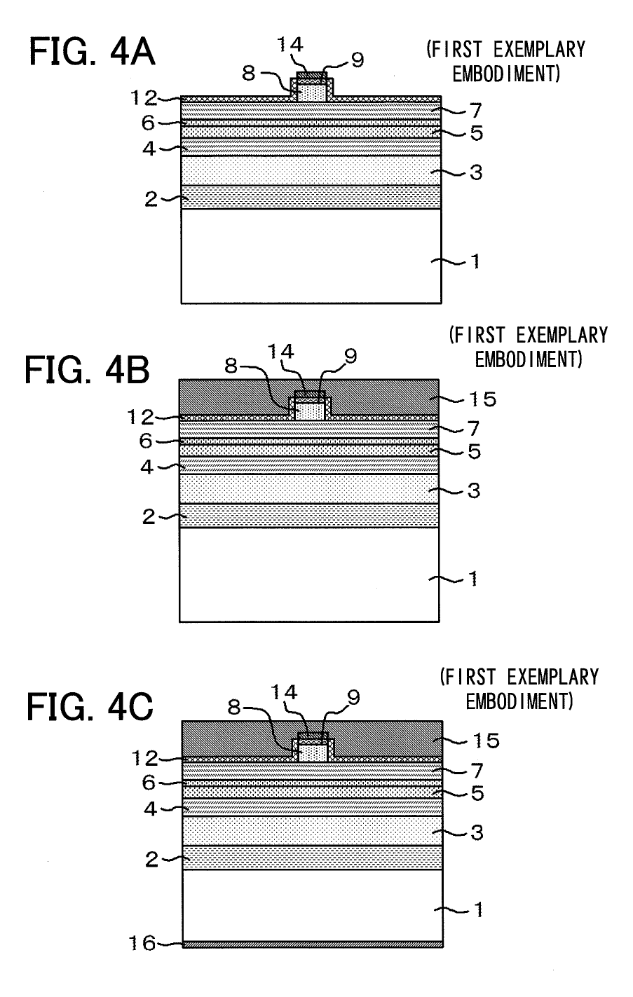

Next, by removing the ridge top portion of the SiO₂ film 12 by buffered hydrofluoric acid, thereafter depositing Pd/Pt by an electronic beam, and by liftoff (removal of the resist 13 and Pd/Pt thereon), the p-type electrode 14 is formed on the p-type contact layer 9 (step A7; refer to FIG. 4A).

Next, RTA (Rapid Thermal Annealing) for 30 seconds at 600° C. in a nitrogen atmosphere is performed, a p-ohmic electrode is formed, and thereafter, by depositing Pt of 100 nm and Au of 2 μm, by sputtering, the cover electrode 15 is formed (step A8; refer to FIG. 4 B).

Next, by polishing a wafer back surface (back surface of the n-type GaN substrate 1), thinning the wafer thickness to a thickness of 100 μm, and performing vacuum deposition of Ti at 5 nm, Al at 20 nm, Ti at 10 nm and Au at 500 nm, in order, from the n-type GaN substrate 1 side, the n-type electrode 16 is formed (step A9; refer to FIG. 4C).

Next, the wafer after forming the electrode 16 is cleaved in a direction perpendicular to a longitudinal axis of the p-type cladding layer 8 of a stripe form, and a laser bar of a resonator length 600 μm is formed (step A10).

Next, the edge surface protective film is formed on the resonator edge surfaces of the laser bar, made by step A10 (step A11). A dielectric film, fabricated by a method such as a vacuum deposition method or a sputtering method, is used for the edge surface protective film. In formation of the edge surface protective film, it is possible to use an RF magnetron sputtering apparatus.

In formation of the edge surface protective film, first, the AR film 20 that has a reflectance of 0.1 to 22% is formed on the laser beam emission side edge surface (refer to FIG. 1B), and then the HR film that has a reflectance of greater than or equal to 90% is formed on an edge surface of a side opposite thereto. Details are as follows.

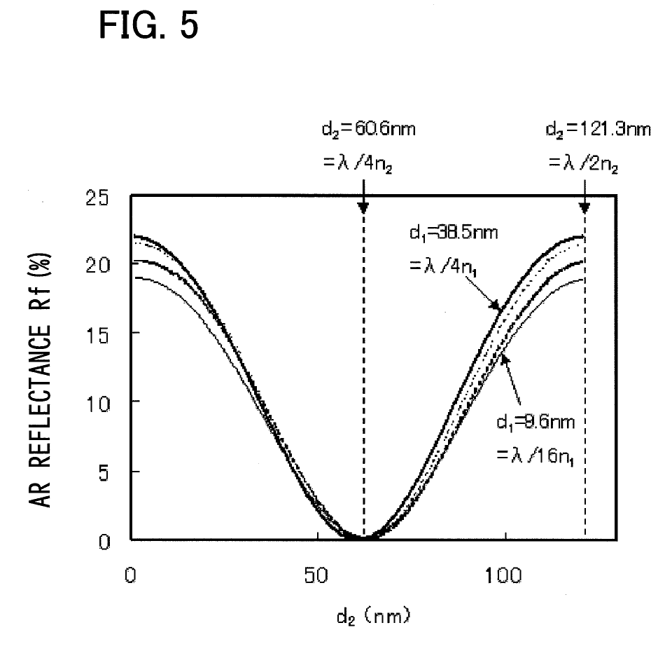

The laser bar, made by step A10 is inserted into a load lock chamber of the RF magnetron sputtering apparatus, and heat treatment at 200° C. for 0 to 60 minutes is performed. Thereafter, it is conveyed to a sputtering chamber; when an attained vacuum inside the sputtering apparatus has reached 6×10⁻⁵ Pa, Ar is introduced into the sputtering apparatus; after setting a pressure of Ar gas to a range of 0.4 to 3.3 Pa, film formation with TiO₂ as the first protective film 21 is performed; then film formation with Al₂O₃ as the second protective film 22 is performed; and the AR film 20 is realized. Respective sputtering targets can use high purity TiO₂ and Al₂O₃, and input power can be 0.2 to 1.2 kW, for instance. The respective thicknesses d₁ and d₂ of TiO₂ and Al₂O₃ are in ranges of 0<d₁≦λ/4n₁ and 0<d₂≦λ/2n₂. Here, λ is laser oscillation wavelength 405 nm, n₁ is the refractive index 2.6 of TiO₂ with regard to 405 nm, and n₂ is the refractive index 1.7 of Al₂O₃ with regard to 405 nm. When the refractive index of GaN is 2.5, by having d₁ and d₂ in the abovementioned ranges, preferred control is possible with the AR reflectance (below, termed as “Rf”) in a range of 0.1 to 22% (refer to FIG. 5).

After the laser bar, with the AR film 20 formed, was taken out once from the sputtering apparatus, the HR film with reflectance of 90% formed of a SiO₂/TiO₂ multilayer film was formed on the edge surface of the opposite side again in the sputtering apparatus.

Thereafter, device separation of the laser bar, in which the edge surface protective film is formed, is carried out (step A12). Here, a laser chip with a device width of 300 μm was fabricated.

The laser chip obtained by the abovementioned processes is attached to a heat sink by fusing (step A13). In this way, it is possible to obtain a nitride semiconductor.

### Hydrogen Concentration Distribution

Next, hydrogen concentration distribution in the AR film 20 in the semiconductor laser according to the first exemplary embodiment of a present invention is described.

The hydrogen concentration distribution in the AR film 20 was obtained by SIMS analysis (Secondary Ion-microprobe Mass Spectrometry). As an analysis test sample, usage was made of a multilayer film that is formed with the same configuration as the AR film 20 formed in the semiconductor laser according to the first exemplary embodiment and under the same film formation conditions, on a cleavage surface of the GaN substrate of 400 μm thickness.

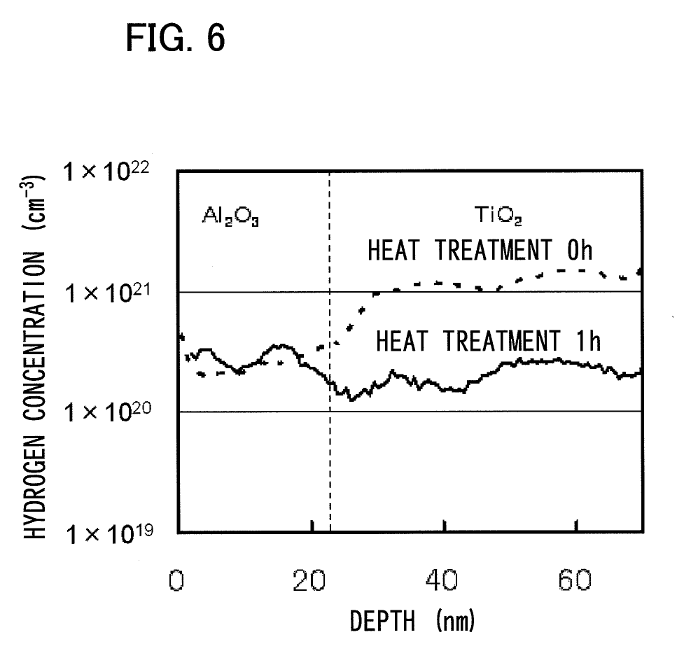

One example of a result is shown in FIG. 6. In a case of film formation without carrying out heat treatment (heat treatment of 0 h), the hydrogen concentration in the TiO₂ was approximately 1.3×10²¹ cm⁻³, the hydrogen concentration in the Al₂O₃ was approximately 2.1×10²⁰ cm⁻³, and a ratio thereof was 6.2. On the other hand, in a case in which heat treatment of 1 h was carried out, the hydrogen concentration in the TiO₂ was approximately 2.5×10²⁰ cm⁻³, the hydrogen concentration in the Al₂O₃ was approximately 2.2×10²⁰ cm⁻³, and a ratio thereof was 1.1, say, within a range of 1≠0.1, approximately.

### Internal Stress

Next, the internal stress of the AR film 20 in the semiconductor laser according to the first exemplary embodiment of the present invention is described.

First, with regard to a GaAs substrate, a single layer film of 100 nm thickness was formed with film formation conditions the same as each dielectric film constituting the AR film formed in the semiconductor laser device of the first exemplary embodiment, overall warp amount was measured, and the internal stress of each dielectric film was obtained from the numerical formula below.

σ=Eb2δ/3(1−ν)l2d Numerical Formula 1

In Numerical Formula 1, E is Young's modulus of the GaAs substrate, ν is Poisson's ratio of the GaAs substrate, l is the length of the GaAs substrate, b is the thickness of the GaAs substrate, d is the thickness of the single layer protective film, and δ indicates displacement. Here, for E, the Young's modulus of GaAs is assigned a value, and for ν, the Poisson's ratio of GaAs is assigned a value. That is, the Young's modulus of GaAs was taken as 8.5×1010 (Pa), and the Poisson's ratio was taken as 0.32.

When the sign of the internal stress obtained from the abovementioned Numerical Formula 1 is −, compressive stress is indicated, and when the sign is +, tensile stress is indicated.

The total stress S of the AR film 20 was obtained from the following Numerical Formula 2 as the total of the products of the respective film thicknesses (d₁, d₂) and the film stresses (σ₁, σ₂) of the first and second protective films obtained from the above-mentioned formula.

S=σ₁×d₁+σ₂×d₂ Numerical Formula 2

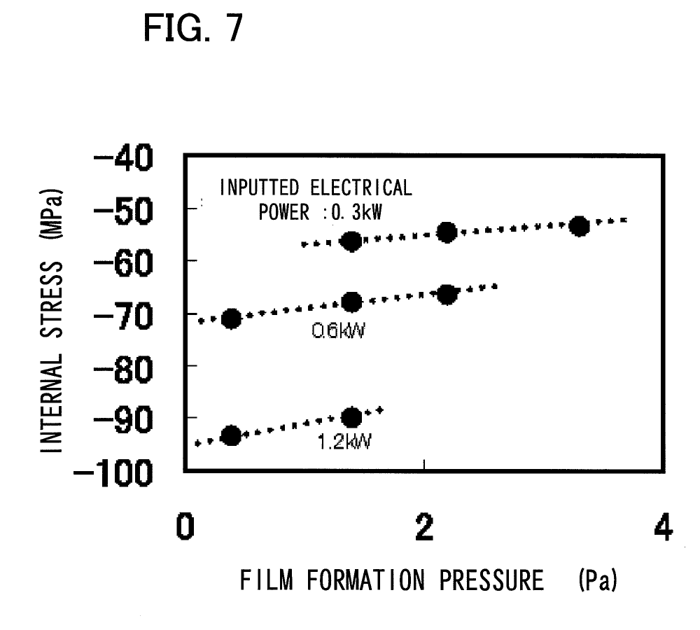

The internal stress σ of the dielectric film formed by the sputtering method can be controlled by the film formation condition. As an example, FIG. 7 shows a film formation condition dependency of internal stress of Al₂O₃. In general, the higher the sputter pressure, or the lower the target input electrical power, the lower the energy of sputter particles. As a result, migration of sputter seed that has reached the substrate surface is inhibited, so that the film density decreases, and since additionally an ion peening effect decreases, the compressive stress of the dielectric film decreases. Furthermore, the test sample temperature, distance between the test sample and target, and gas type (oxygen, nitrogen, hydrogen) added at film formation are also influential. These have a relationship with density and there is a wide variety of preferable ranges, but based on a result of an investigation by the inventors, is was understood that input electrical power of 0.1 to 2.4 kW, Ar gas pressure of 0.1 to 4 Pa, distance between test sample and target of 50 to 120 mm, and test sample temperature of 25 to 300° C. are preferable. In the first exemplary embodiment, with the distance between the test sample and target of 80 mm and the test sample temperature at 200° C., the AR film 20 indicated in the following table was formed.

TABLE 1

| First Protective Film: TiO₂ | | | | Second Protective Film: Al₂O₃ | | | | | |
|---|---|---|---|---|---|---|---|---|---|
| (refractive index n₁ = 2.6) | | | | (refractive index n₂ = 1.7) | | | | | |
| Inputted | | Film | Internal | Inputted | | Film | Internal | Total | Front Surface |
| Electrical | | Thickness | Stress | Electrical | | Thickness | Stress | Stress | Reflectance |
| Power | Pressure | d₁ | σ₁ | Power | Pressure | d₂ | σ₂ | S | Rf |
| (kW) | (Pa) | (nm) | (MPa) | (kW) | (Pa) | (nm) | (MPa) | (N/m) | (%) |
| 0.2 | 1.4 | 38.5 | −28 | 0.6 | 1.4 | 25.0 | −68 | −2.8 | 15 |
| 0.2 | 1.4 | 38.5 | −28 | 0.6 | 1.4 | 12.0 | −68 | −1.9 | 20 |
| 0.2 | 1.4 | 38.5 | −28 | 0.6 | 1.4 | 43.0 | −68 | −4.0 | 5 |
| 0.2 | 1.4 | 38.5 | −28 | 0.6 | 1.4 | 96.0 | −68 | −7.6 | 15 |
| 0.2 | 1.4 | 3.8 | −28 | 0.6 | 1.4 | 25.0 | −68 | −1.8 | 13 |
| 0.2 | 1.4 | 9.6 | −28 | 0.6 | 1.4 | 25.0 | −68 | −2.0 | 14 |
| 0.2 | 1.4 | 19.2 | −28 | 0.6 | 1.4 | 25.0 | −68 | −2.2 | 15 |
| 0.2 | 1.4 | 9.6 | −28 | 0.3 | 3.3 | 25.0 | −54 | −1.6 | 14 |
| 0.2 | 1.4 | 9.6 | −28 | 1.2 | 0.4 | 25.0 | −93 | −2.6 | 14 |

### Life Span Test

Next, the life span (durable life) of the semiconductor laser according to the first exemplary embodiment of the present invention is described.

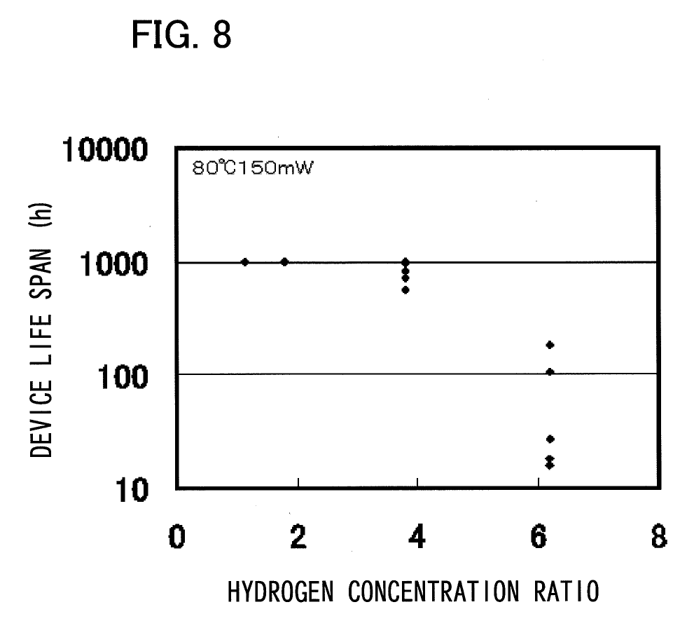

FIG. 8 is a drawing showing a relationship of device life span in an 80° C., 150 mW APC test, and hydrogen concentration ratio in the AR film. In FIG. 8, the device life span has an upper limit of 1000 h, and plotting is made of time at which devices whose device life span is less than 1000 h by driving stop due to sudden deterioration caused by COD (Catastrophic Optical Damage) of the laser beam emission edge surface. Here, thicknesses (d₁, d₂) and film formation conditions of the first protective film (TiO₂) and the second protective film (Al₂O₃) are respectively constant for TiO₂: at 0.2 kW, 1.4 Pa, d₁=38.5 nm, and for Al₂O₃: 0.6 kW, 1.4 Pa, and d₂=25 nm, and by changing heat treatment time before film formation to 0, 20, 40, 60 min, the hydrogen concentration ratio is varied.

At this time, front surface reflectance was Rf=15%, the internal stress of each of the protective films was σ₁=−30 MPa, σ₂=−60 MPa, and total stress was S=−2.8 N/m. Furthermore, the hydrogen concentration ratios (hydrogen concentration in TiO₂/hydrogen concentration in Al₂O₃) were, respectively, 6.2, 3.8, 1.8, and 1.1.

As is apparent from FIG. 8, as the hydrogen concentration ratio approaches 1, that is, as the hydrogen distribution in the AR film 20 becomes flat, the device life span is rapidly improved, and at a hydrogen concentration ratio of 2 or less, the sudden deterioration due to COD is inhibited. With regard to the AR film 20, even if a size relationship of the hydrogen concentration between the first protective film 21 and the second protective film 22 is reversed, (even if the hydrogen concentration ratio is less than 1; even if the hydrogen concentration of the first protective film 21 is less than the hydrogen concentration of the second protective film 22), a similar effect is obtained.

In order to investigate a reason for this improvement effect, a device having a hydrogen concentration ratio of 6.2 and a device having a hydrogen concentration ratio of 1.1 are driven for 100 hours at 80° C. and 100 mW, and an analysis of a vicinity of the edge surface of the AR film 20 was performed by a cross-section TEM (transmission electron microscope).

As a result, in the device with the hydrogen concentration ratio of 6.2, the AR film expanded in a vicinity of the active layer, and in this region a gap occurred in an surface interface between the semiconductor and the TiO₂, whereas in the device with the hydrogen concentration ratio of 1.1, this type of gap (film delamination) was not confirmed.

From these results, it was understood that, in a case where the hydrogen concentration distribution in the AR film 20 is high, device reliability decreases due to COD level decreasing by local delamination of the AR film 20, and by flattening the hydrogen concentration distribution in the AR film 20 by heat treatment before the film formation, it is possible to inhibit this type of edge surface deterioration.

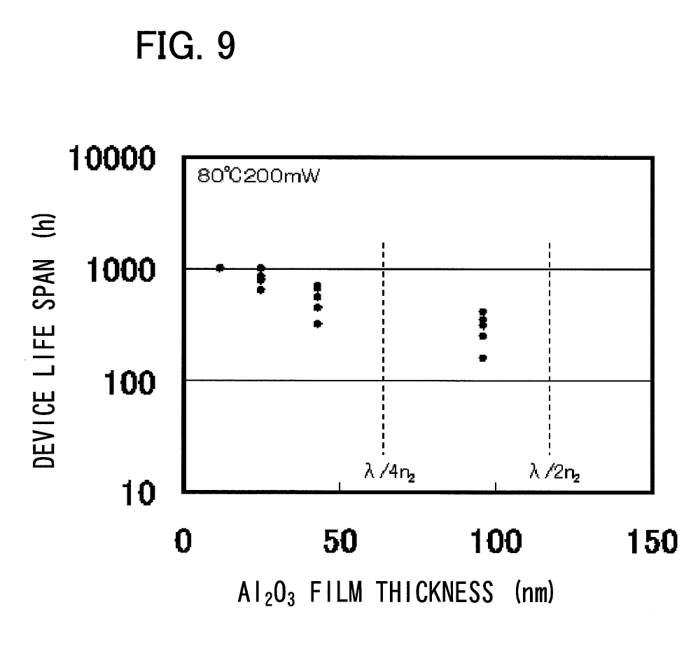

FIG. 9 is a drawing showing a relationship of Al₂O₃ thickness and device life span with regard to a cross-section TEM observation (80° C., 200 mW APC test) after driving for 100 h at 80° C. and 200 mW. Here, the heat treatment time before the film formation is 1 h, film formation conditions and thicknesses (d₁, d₂) of the TiO₂ and the Al₂O₃ are respectively for TiO₂: 0.2 kW, 1.4 Pa, d₁=38.5 nm, and for Al₂O₃:0.6 kW, 1.4 Pa, d₂=12, 25, 43, and 96 nm. At this time, the internal stress of each protective film is σ₁=−28 MPa, σ₂=−68 MPa, and the total stress S and Rf are respectively S=−1.9, −2.8, −4, −7.6 N/m, Rf=205, 5, 15%. Since the lower Rf of a device, the more the edge surface light density decreases, the initial COD level indicates a high value, but, as shown in FIG. 9, with regard to the reliability, not depending on Rf, the thinner the Al₂O₃ thickness of the device, the more improvement there is. In addition, by a cross-section TEM observation after driving for 100 h at 80° C. and 200 mW, for a device having d₂=96 nm (Rf=15%, and total stress S=−7.6 N/m), film delamination of the AR film 20 was confirmed.

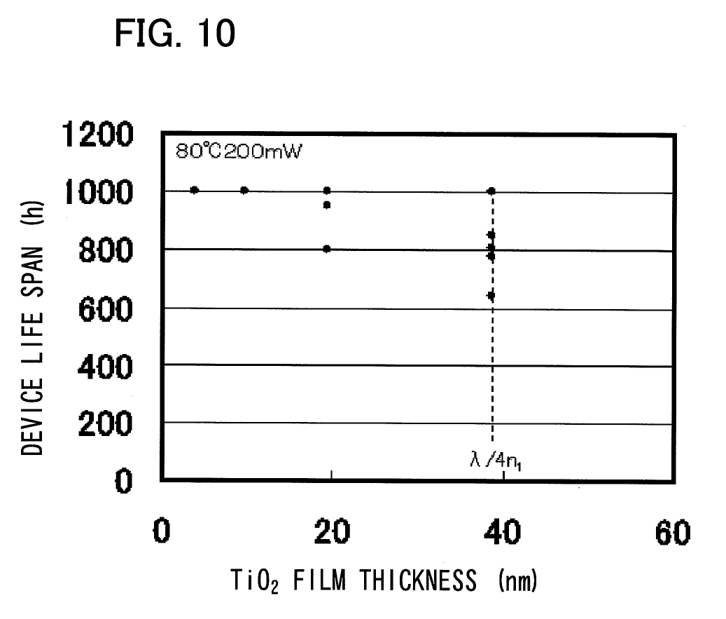

FIG. 10 is a drawing showing a relationship of TiO₂ thickness and device life span with regard to a cross-section TEM observation (80° C., 200 mW APC test) after driving for 100 h at 80° C. and 200 mW. Here, the heat treatment time before film formation is 1 h, and film formation conditions and thicknesses (d₁, d₂) of the TiO₂ and the Al₂O₃ are respectively for TiO₂: 0.2 kW, 1.4 Pa, d₁=3.8, 9.6, 19.2, 38.5 nm; and for Al₂O₃: 0.6 kW, 1.4 Pa, d₂=25 nm. At this time, the internal stress of each protective film is constant at σ₁=−28 MPa, σ₂=−68 MPa, and the total stress S and Rf are respectively S=−1.8, −2.0, −2.2, 2.8 N/m, and Rf=114, 15, 15%. As shown in FIG. 10, the thinner TiO₂ is in a device, the more the reliability is improved, and in a device with d₁≦10 nm, the COD deterioration for less than 1000 h is inhibited.

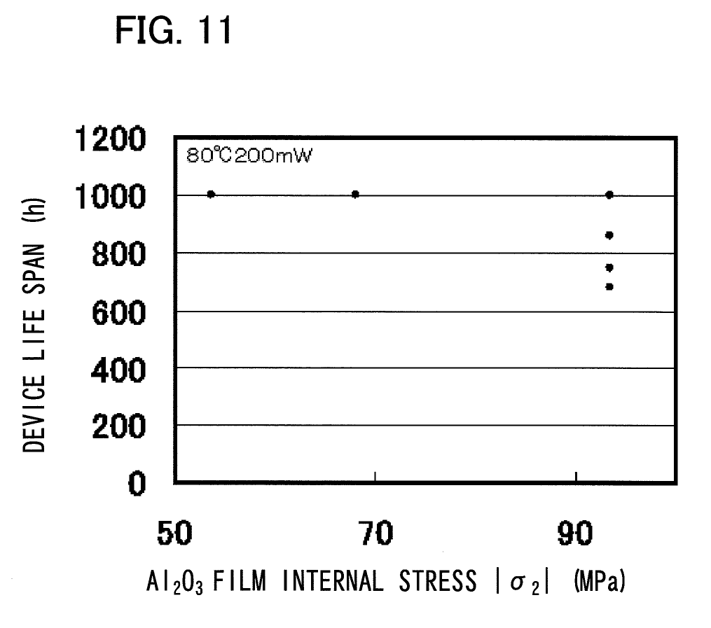

FIG. 11 is a drawing showing a relationship of Al₂O₃ film stress and device life span with regard to a cross-section TEM observation (80° C., 200 mW APC test) after driving for 100 h at 80° C. and 200 mW. Here, the heat treatment time before film formation is 1 h, and film formation conditions and thicknesses (d₁, d₂) of the TiO₂ and the Al₂O₃ are respectively for TiO₂: 0.2 kW, 1.4 Pa, d₁=9.6 nm; and for Al₂O₃: 0.3 kW, 3.3 Pa; 0.6 kW, 1.4 Pa; 1.2 kW, 0.4 Pa; d₂=25 nm. At this time, the internal stress of the TiO₂ is constant at σ₁=−28 MPa, Rf is constant at 14%, and the internal stress of the Al₂O₃ σ₂ and the total stress S are respectively σ₂=−54, 68, 93 MPa, S=−1.6, −2.0, −2.6 N/m. As is apparent from FIG. 11, the more the internal stress σ₂ of the Al₂O₃ decreases, the more the reliability is improved.

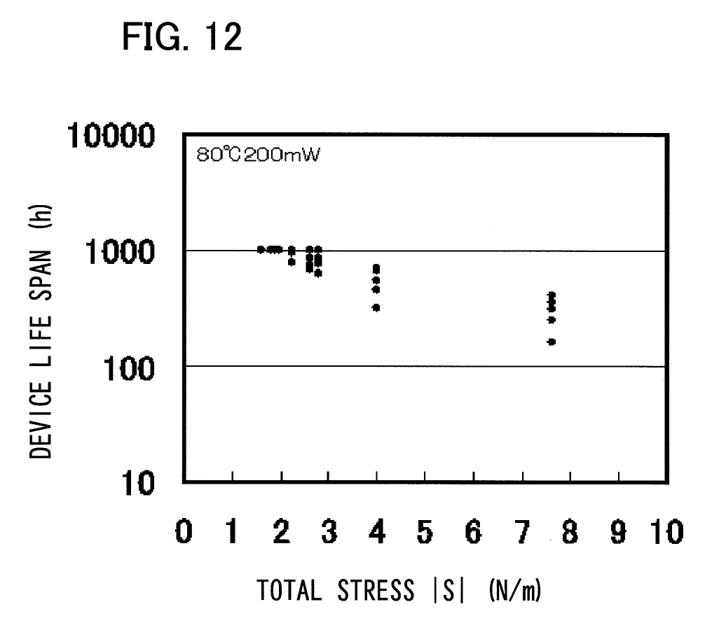

FIG. 12 is a drawing showing a relationship of AR total stress and device life span with regard to a cross-section TEM observation (80° C., 200 mW APC test) after driving for 100 h at 80° C. and 200 mW, obtained based on results shown in FIG. 9, FIG. 10, and FIG. 11. As is apparent from FIG. 12, it was understood that the more the total stress S in a direction of compression decreases, the more the reliability improves, and by having an absolute value of the total stress S less than or equal to 2, it is possible to completely inhibit COD occurrence at less than 1000 hours.

From the abovementioned results, the following model can be considered with regard to edge surface destruction.

In a device edge surface of a semiconductor laser when driving at high output, due to absorption of the laser beam caused by an interfacial degeneration layer or point defects introduced at surface level or when forming the protective film, the temperature of a laser beam emission portion increases locally. Since the edge surface protective film formed on the laser beam emission edge surface expands due to this generation of heat, compressive stress on the protective film, due to difference of thermal expansion coefficient from the semiconductor, increases, and local film delamination occurs.

Furthermore, in a case where the hydrogen concentration of the AR film is not uniform, the hydrogen in a vicinity of a light emitting part when driving at high output is diffused easily from a high concentration region to a low concentration region. As a result, since the stress distribution in the AR film changes locally, film delamination easily occurs. As a cause for the distribution occurring in the hydrogen concentration, organic impurities attached to the edge surface before film formation, moisture, and the like, could be considered.

Furthermore, since for a nitride semiconductor growth layer, growth is carried out in a hydrogen atmosphere, the possibility may be considered that this will precipitate. Therefore, in improving the reliability of the semiconductor laser, making the hydrogen concentration distribution in the film uniform, and reducing the total stress in the film are extremely effective.

With regard to the internal stress in the AR film, the film type thereof and film formation method differ according to conditions, but in general, compressive stress of the order of several 10s (tens) to several 100s (hundreds) MPa is applied to the dielectric film formed by sputtering, and it is difficult to make this 0. Consequently, in the first exemplary embodiment, as a result of performing optimization of the film formation conditions, having selected a low refractive index material and a high refractive index material to obtain a desired reflectance with as thin a film thickness as possible, it is possible to obtain a semiconductor laser with high output and high reliability.

In the present invention there are various preferred modes as follows;

Mode 1. as mentioned as “one aspect” at [0015].
Mode 2. The semiconductor laser according to mode 1, wherein the active layer is formed of a group-III nitride semiconductor including Ga as a constituent element.
Mode 3. The semiconductor laser according to mode 1, wherein

the protective film is formed of at least a first protective film that is in direct contact with the edge surface of the active layer, and a second protective film that is in contact with the first protective film; and

a ratio of hydrogen concentration of the first protective film with respect to hydrogen concentration of the second protective film is not less than 0.5 and not more than 2.

Mode 4. The semiconductor laser according to any one of modes 1 to 3, wherein, in the protective film, a dielectric film that is in direct contact with at least the edge surface of the active layer comprises at least one of Ti, Zr, Nb, Ca, and Mg.
Mode 5. The semiconductor laser according to any one of modes 1 to 4, wherein, in the protective film, a dielectric film that is in direct contact with at least the edge surface of the active layer is formed of TiO₂.
Mode 6. The semiconductor laser according to any one of modes 1 to 5, wherein

the protective film is formed of a first protective film that is in direct contact with the edge surface of the active layer, and a second protective film that is in contact with the first protective film;

for a laser oscillation wavelength λ, a refractive index n₁ of the first protective film and a refractive index n₂ of the second protective film satisfy a relationship n₁>n₂;

thickness d₁ of the first protective film satisfies d₁≦λ/4n₁; and

thickness d₂ of the second protective film satisfies d₂≦λ/2n₂.

Mode 7. The semiconductor laser according to mode 6 wherein thickness d₁ of the first protective film is less than or equal to 10 nm.
Mode 8. The semiconductor laser according to any one of modes 1 to 7, wherein size of total stress in a direction of compression acting on the protective film is larger than 0 N/m and not more than 10 N/m.
Mode 9. The semiconductor laser according to any one of modes 1 to 8, comprising a second protective film arranged on an edge surface of an opposite side to the edge surface from which the laser beam is emitted, the second protective film having a reflectance higher than the protective film arranged on the edge surface from which the laser beam is emitted.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor laser for emitting a laser beam from an edge surface of an active layer, said laser comprising:
a protective film arranged on said edge surface from which said laser beam is emitted, and formed of a single-layer or a multilayer dielectric film; wherein
hydrogen concentration distribution in said protective film is approximately flat.

2. The semiconductor laser according to claim 1, wherein said active layer is formed of a group-III nitride semiconductor including Ga as a constituent element.

3. The semiconductor laser according to claim 1, wherein
said protective film is formed of at least a first protective film that is in direct contact with said edge surface of said active layer, and a second protective film that is in contact with said first protective film; and
a ratio of hydrogen concentration of said first protective film with respect to hydrogen concentration of said second protective film is not less than 0.5 and not more than 2.

4. The semiconductor laser according to claim 1, wherein, in said protective film, a dielectric film that is in direct contact with at least said edge surface of said active layer comprises at lease one of Ti, Zr, Nb, Ca, and Mg.

5. The semiconductor laser according to claim 1, wherein, in said protective film, a dielectric film that is in direct contact with at least said edge surface of said active layer is formed of TiO₂.

6. The semiconductor laser according to claim 1, wherein
said protective film is formed of a first protective film that is in direct contact with said edge surface of said active layer, and a second protective film that is in contact with said first protective film;
for a laser oscillation wavelength λ, a refractive index n₁ of said first protective film and a refractive index n₂ of said second protective film satisfy a relationship n₁>n₂;
thickness d₁ of said first protective film satisfies d₁≦λ/4n₁; and
thickness d₂ of said second protective film satisfies d₂≦λ/2n₂.

7. The semiconductor laser according to claim 6 wherein thickness d₁ of said first protective film is less than or equal to 10 nm.

8. The semiconductor laser according to claim 1, wherein size of total stress in a direction of compression acting on said protective film is larger than 0 N/m and not more than 10 N/m.

9. The semiconductor laser according to claim 1, comprising a second protective film arranged on an edge surface of an opposite side to said edge surface from which said laser beam is emitted, said second protective film having a reflectance higher than said protective film arranged on said edge surface from which said laser beam is emitted.
